(19) United States
(12) Patent Application Publication
(10) Pub. No.: US 2025/0201679 A1
(43) Pub. Date: Jun. 19, 2025

(54) SEMICONDUCTOR DEVICE

(71) Applicant: DENSO CORPORATION, Kariya-city (JP)

(72) Inventors: Mitsuki KAWANO, Kariya-city (JP); Nobuyuki KATO, Kariya-city (JP)

(21) Appl. No.: 19/067,182

(22) Filed: Feb. 28, 2025

Related U.S. Application Data
(63) Continuation of application No. PCT/JP2023/030170, filed on Aug. 22, 2023.

(30) Foreign Application Priority Data
Sep. 2, 2022 (JP) 2022-140168

(51) Int. Cl. H01L 23/495; H01L 23/00; H01L 25/07; H02M 7/00

(52) U.S. Cl. CPC H01L 23/49562; H01L 23/49524; H01L 23/49537; H01L 23/49568; H01L 24/29; H01L 24/32; H01L 24/48; H01L 25/072; H02M 7/003; H01L 2224/27013; H01L 2224/29111; H01L 2224/29147; H01L 2224/32245; H01L 2224/48175; H01L 2924/13055; H01L 2924/13091

(57) ABSTRACT

A semiconductor device includes semiconductor elements and conductors. The conductors include a first upper conductor connected to an upper electrode of the first semiconductor element through a first upper solder, a first lower conductor connected to a lower electrode of the first semiconductor element through a first lower solder, a second upper conductor connected to an upper electrode of the second semiconductor element through a second upper solder, a second lower conductor connected to a lower electrode of the second semiconductor element through a second lower solder, and a joint conductor connecting the first upper conductor and the second lower conductor through a relay solder. Each solder contains Cu and Sn. Each solder connection target has an Ni layer. A grain size of at least one of the first upper solder, second upper solder, or relay solder is smaller than a grain size of the first and second lower solders.

### CROSS REFERENCE TO RELATED APPLICATIONS

The present application is a continuation application of International Patent Application No. PCT/JP2023/030170 filed on Aug. 22, 2023, which designated the U.S. and claims the benefit of priority from Japanese Patent Application No. 2022-140168 filed on Sep. 2, 2022. The entire disclosures of all of the above applications are incorporated herein by reference.

### TECHNICAL FIELD

The present disclosure relates to a semiconductor device.

### BACKGROUND

JP 2016-92166 A discloses a semiconductor device having a semiconductor element that constitutes an upper arm of an upper-lower arm circuit and a semiconductor element that constitutes a lower arm of the upper-lower arm circuit. The disclosure of JP 2016-92166 A is incorporated herein by reference as the description of technical elements of the present disclosure.

### SUMMARY

The present disclosure describes a semiconductor device including a first semiconductor element, a second semiconductor element, and a plurality of conductors. The plurality of conductors includes a first upper conductor connected to an upper electrode of the first semiconductor element through a first upper solder, a first lower conductor connected to a lower electrode of the first semiconductor element through a first lower solder, a second upper conductor connected to an upper electrode of the second semiconductor element through a second upper solder, a second lower conductor connected to a lower electrode of the second semiconductor element through a second lower solder, and a joint conductor connecting the first upper conductor and the second lower conductor through a relay solder. Each solder contains Cu and Sn. Each solder connection target has an Ni layer. A grain size of at least one of the first upper solder, second upper solder, or relay solder is smaller than a grain size of the first and second lower solders.

### BRIEF DESCRIPTION OF DRAWINGS

Features and advantages of the present disclosure will become more apparent from the following detailed description made with reference to the accompanying drawings, in which:

FIG. 1 is a diagram illustrating a schematic configuration of a vehicle drive system to which a semiconductor device according to a first embodiment is applied;

FIG. 2 is a plan view of the semiconductor device according to the first embodiment;

FIG. 3 is a cross-sectional view taken along a line III-III in FIG. 2;

FIG. 4 is a cross-sectional view taken along a line IV-IV in FIG. 2;

FIG. 5 is a plan view of the semiconductor device from which a sealing body is removed;

FIG. 6 is a plan view of the semiconductor device from which a heat sink on an emitter electrode side is removed;

FIG. 7 is a diagram illustrating an output current and a reverse current;

FIG. 8 is an enlarged cross-sectional view of a region VIII in FIG. 3;

FIG. 9 is an enlarged cross-sectional view of the vicinity of a solder joint surface of a joint portion;

FIG. 10 is a cross-sectional view of a reference example;

FIG. 11 is a reference diagram illustrating the mechanism of progression of electromigration (EM);

FIG. 12 is a plan view illustrating modifications;

FIG. 13 is an enlarged cross-sectional view of the vicinity of a solder joint surface of a joint portion in a semiconductor device according to a second embodiment;

FIG. 14 is a plan view of a heat sink including a joint portion in a semiconductor device according to a third embodiment;

FIG. 15 is an enlarged view of a region XV in FIG. 14;

FIG. 16 is a cross-sectional view illustrating a solder joint structure of a joint portion in a semiconductor device according to a fourth embodiment; and

FIG. 17 is a cross-sectional view illustrating a modification.

### DETAILED DESCRIPTION

There is a semiconductor device having a semiconductor element that constitutes an upper arm of an upper-lower arm circuit and a semiconductor element that constitutes a lower arm of the upper-lower arm circuit. Such a semiconductor device has a joint conductor that connects, with solder, a conductor connected to a lower potential side main electrode of the semiconductor element that constitutes the upper arm and a conductor connected to a higher potential side main electrode of the semiconductor element that constitutes the lower arm. A joined area of a solder joined portion of the joint conductor with the solder is small. The joint conductor is provided with a nickel (Ni) layer in order to suppress progress of electromigration (EM) in the solder joined portion of the joint conductor.

As carbon neutrality is advocated and the shift to electric vehicles continues, semiconductor devices are required to be even smaller and have higher current capacity. In other words, further improvements are required to improve the EM lifetime. From the above-described viewpoint or from other viewpoints not mentioned, further improvement is required for the semiconductor device.

The present disclosure provides a semiconductor device capable of improving the EM lifetime.

According to an aspect of the present disclosure, a semiconductor device includes: a plurality of semiconductor elements each having a signal pad and an upper electrode as a main electrode on an upper surface, and a lower electrode as a main electrode on a lower surface, which is opposite to the upper surface in a thickness direction, the lower electrode having an area larger than that of the upper electrode in a plan view when viewed in the thickness direction; and a plurality of conductors electrically connected to the main electrodes through a plurality of solders. The plurality of semiconductor elements includes a first semiconductor element constituting an upper arm of an upper-lower arm circuit, and a second semiconductor element constituting a lower arm of the upper-lower arm circuit. The first semiconductor element and the second semiconductor element are arranged side by side in an arrangement direction perpendicular to the thickness direction so that the upper surface of the first semiconductor element and the upper surface of the second semiconductor element are on a same side in the thickness direction. The plurality of solders includes a first upper solder, a first lower solder, a second upper solder, a second lower solder, and a relay solder. The plurality of conductors includes a first upper conductor connected to the upper electrode of the first semiconductor element through the first upper solder, a first lower conductor connected to the lower electrode of the first semiconductor element through the first lower solder, a second upper conductor connected to the upper electrode of the second semiconductor element through the second upper solder, a second lower conductor connected to the lower electrode of the second semiconductor element through the second lower solder, and a joint conductor connecting the first upper conductor and the second lower conductor through the relay solder. Each of the plurality of solders contains copper (Cu) and tin (Sn). Each of solder connection targets to be connected through at least one of the plurality of solders has a nickel (Ni) layer. A grain size of at least one of the first upper solder, the second upper solder, or the relay solder is smaller than a grain size of the first lower solder and a grain size of the second lower solder.

In a configuration in which the upper electrode is smaller than the lower electrode and the joint conductor is provided, the current density in the first upper solder, the second upper solder and the relay solder will be higher than the current density in the first lower solder and second lower solder. In the semiconductor device according to the aspect described above, the grain size of at least one of the first upper solder, the second upper solder, or the relay solder, which has the high current density, is smaller than the grain size of the first lower solder and the second lower solder. This configuration can slow down the disappearance of the Ni layer due to the EM. As a result, the semiconductor device with improved the EM lifetime can be provided.

Hereinafter, multiple embodiments will be described with reference to the drawings. The same or corresponding elements are denoted by the same reference numerals throughout the embodiments, and descriptions thereof will not be repeated. When only part of the configuration is described in each embodiment, the configuration of the other preceding embodiments can be applied to the other parts of the configuration. Further, not only the combinations of the configurations explicitly shown in the description of the respective embodiments, but also combinations of the configurations of the multiple embodiments which are not explicitly shown can be applicable as long as there is no difficulty in such combinations in particular.

A semiconductor device according to the present embodiment is applicable to, for example, a power conversion device for a mobile object having a rotary electric machine as a drive source. Examples of the mobile object include an electrically driven vehicle such as a battery electric vehicle (BEV), a hybrid electric vehicle (HEV), or a plug-in hybrid electric vehicle (PHEV), a flying object, a ship, a construction machine, or an agricultural machine. The flying object may be, for example, an electric vertical takeoff and landing aircraft or a drone. Hereinafter, an example in which the semiconductor device is applied to a vehicle will be described.

### First Embodiment

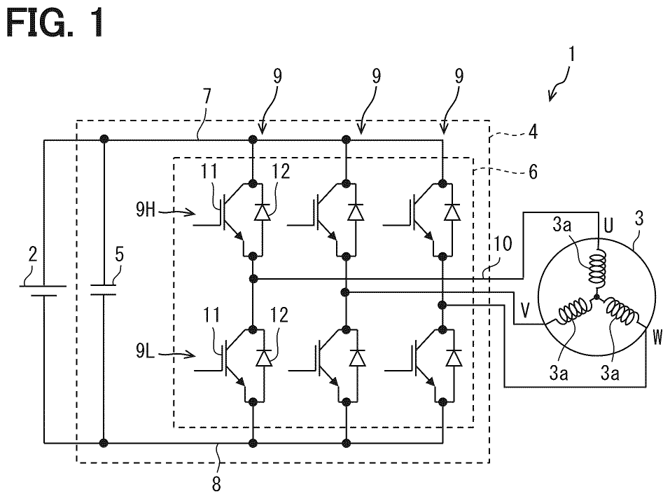

First, a schematic configuration of a vehicle drive system 1 will be described with reference to FIG. 1.

### <Vehicle Drive System>

As shown in FIG. 1, the vehicle drive system 1 is provided with a direct current (DC) power supply 2, a motor generator 3, and an electric power conversion device 4.

The DC power supply 2 is a DC voltage source including a chargeable/dischargeable secondary battery. Examples of the secondary battery includes a lithium ion battery and a nickel hydride battery. The motor generator 3 is a three-phase alternating current (AC) type rotary electric machine. The motor generator 3 functions as a traveling drive source of the vehicle, that is, an electric motor. The motor generator 3 functions also as a generator during regeneration. The electric power conversion device 4 performs electric power conversion between the DC power supply 2 and the motor generator 3.

### <Electric Power Conversion Device>

Next, a circuit configuration of the electric power conversion device 4 will be described with reference to FIG. 1. The electric power conversion device 4 includes a power conversion circuit. As shown in FIG. 1, the electric power conversion device 4 includes a smoothing capacitor 5 and an inverter 6, which is a power conversion circuit.

The smoothing capacitor 5 mainly smoothes the DC voltage supplied from the DC power supply 2. The smoothing capacitor 5 is connected between a P line 7, which is a power line on a high potential side, and an N line 8, which is a power line on a low potential side. The P line 7 is connected to a positive electrode of the DC power supply 2, and the N line 8 is connected to a negative electrode of the DC power supply 2. A positive electrode of the smoothing capacitor 5 is connected to the P line 7 at a position between the DC power supply 2 and the inverter 6. Similarly, a negative electrode of the smoothing capacitor 5 is connected to the N line 8 at a position between the DC power supply 2 and the inverter 6. The smoothing capacitor 5 is connected to the DC power supply 2 in parallel.

The inverter 6 corresponds to a DC-AC conversion circuit. The inverter 6 converts the DC voltage into a three-phase AC voltage according to the switching control by a control circuit (not shown) and outputs the three-phase AC voltage to the motor generator 3. Thereby, the motor generator 3 is driven to generate a predetermined torque. At the time of regenerative braking of the vehicle, the inverter 6 converts the three-phase AC voltage generated by the motor generator 3 by receiving the rotational force from wheels into a DC voltage according to the switching control by the control circuit, and outputs the DC voltage to the P line 7. In this way, the inverter 6 performs bidirectional power conversion between the DC power supply 2 and the motor generator 3.

The inverter 6 includes upper-lower arm circuits 9 for three phases. The upper-lower arm circuit 9 will be referred to as a “leg”. Each of the upper-lower arm circuits 9 includes an upper arm 9H and a lower arm 9L. The upper arm 9H and the lower arm 9L are connected in series between the P line 7 and the N line 8, with the upper arm 9H being on the P line 7 side. A connection point between the upper arm 9H and the lower arm 9L is connected to a winding 3a of a corresponding phase in the motor generator 3 via an output line 10. The inverter 6 has six arms. At least a part of each of the P line 7, the N line 8 and the output line 10 is made of a conductive member such as a bus bar.

Each arm includes, as elements, an insulated gate bipolar transistor (IGBT) 11 and a freewheeling diode 12. In the present embodiment, an n-channel IGBT 11 is used. The diode 12 is connected in anti-parallel to the corresponding IGBT 11. In the upper arm 9H, a collector of the IGBT 11 is connected to the P line 7. In the lower arm 9L, an emitter of the IGBT 11 is connected to the N line 8. An emitter of the IGBT 11 in the upper arm 9H and a collector of the IGBT 11 in the lower arm 9L are connected to each other. An anode of the diode 12 is connected to the emitter of the corresponding IGBT 11, and a cathode of the diode 12 is connected to the collector of the corresponding IGBT 11.

The electric power conversion device 4 may further include a converter as a power conversion circuit. The converter is a DC-DC conversion circuit for converting the DC voltage to a DC voltage with a different value. The converter is disposed between the DC power supply 2 and the smoothing capacitor 5. The converter is configured to include, for example, a reactor and the upper-lower arm circuit 9 as described above. Such a configuration can boost or suppress the voltage. The electric power conversion device 4 may further include a filter capacitor for removing power supply noise from the DC power supply 2. The filter capacitor is provided between the DC power supply 2 and the converter.

The electric power conversion device 4 may include a drive circuit for switching elements constituting the inverter 6 and the like. The drive circuit supplies a drive voltage to the gate of the IGBT 11 of the corresponding arm according to a drive command of the control circuit. The drive circuit drives, that is, turns on and off the corresponding IGBT 11, by applying the drive voltage. The drive circuit may be referred to as a “driver”.

The electric power conversion device 4 may include a control circuit for the switching element. The control circuit generates a drive command for operating the IGBT 11 and outputs the drive command to the drive circuit. The control circuit generates the drive command based on a torque request input from a higher-level electronic control unit (ECU) (not shown) or signals detected by various sensors. Examples of the various sensors include a current sensor, a rotation angle sensor, and a voltage sensor. The current sensor detects a phase current flowing through the winding 3a of each phase. The rotation angle sensor detects a rotation angle of a rotor of the motor generator 3. The voltage sensor detects a voltage across the smoothing capacitor 5. The control circuit outputs, for example, a pulse width modulation (PWM) signal as the drive command. The control circuit is configured to include, for example, a processor and a memory.

### <Semiconductor Device>

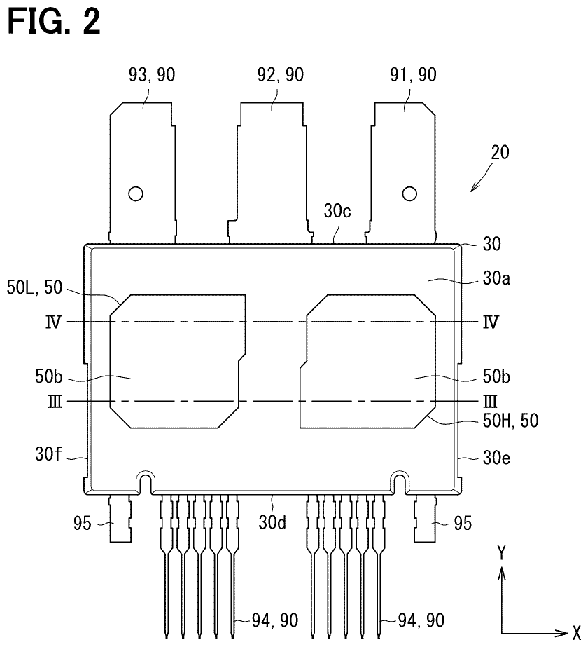

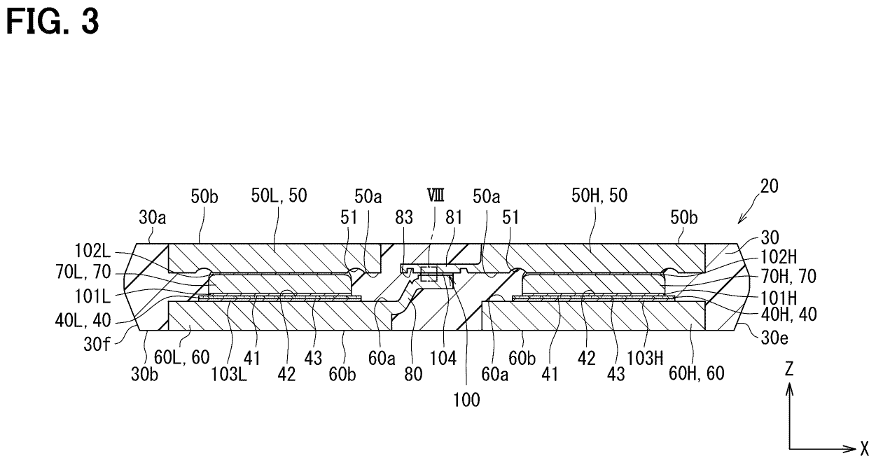

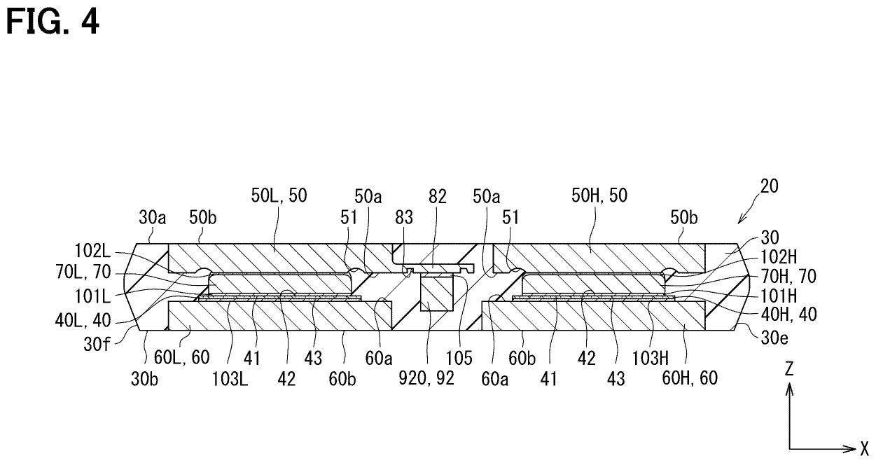

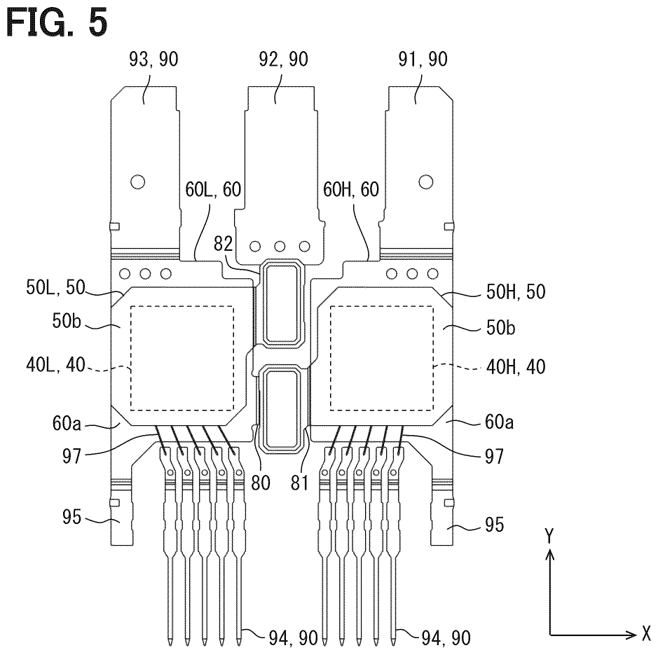

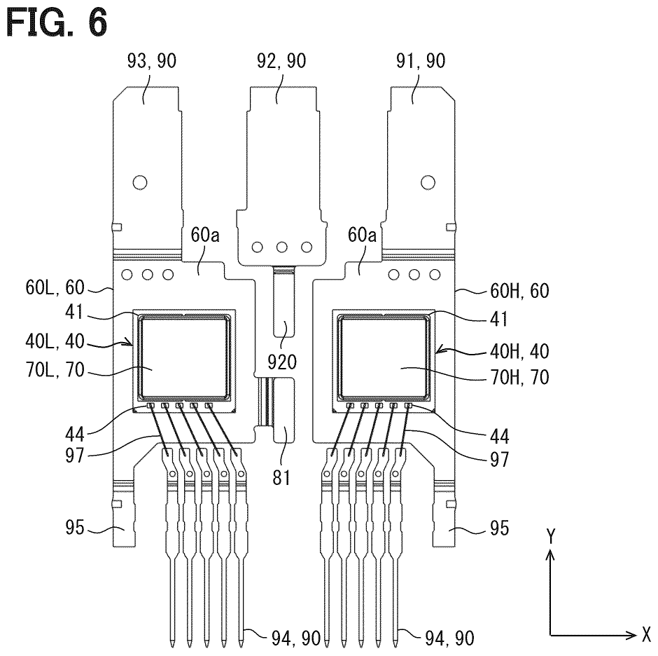

Next, the schematic configuration of the semiconductor device 20 will be described with reference to FIGS. 2 to 6. FIG. 2 is a plan view illustrating the semiconductor device 20. FIG. 2 is a top plan view of the semiconductor device 20. FIG. 3 is a cross-sectional view taken along a line III-III in FIG. 2. FIG. 4 is a cross-sectional view taken along a line IV-IV in FIG. 2. FIG. 5 is a plan view when a sealing body 30 is removed from the semiconductor device 20 shown in FIG. 2. FIG. 6 is a plan view when a heat sink 50 on an emitter electrode 42 side is removed from the semiconductor device shown in FIG. 5.

In regard to some of the elements constituting the semiconductor device, element of the upper arm 9H are denoted by reference numbers with the suffix “H” and element of the lower arm 9L are denoted by reference numbers with the suffix “L”. Some of the other elements of the upper arm 9H and the lower arm 9L are denoted by the same reference numbers for the sake of convenience.

Hereinafter, a thickness direction of a semiconductor element, in other words, a thickness direction of a semiconductor substrate is defined as a Z direction. A direction perpendicular to the Z direction is defined as an X direction. A direction orthogonal to both the Z direction and the X direction is defined as a Y direction. Unless otherwise specified, a shape when viewed along the Z direction, that is, a shape along an XY plane including the X direction and the Y direction is referred to as a planar shape. Further, a plan view when viewed along the Z direction may simply be referred to as a plan view.

As shown in FIGS. 2 to 6, the semiconductor device 20 includes a sealing body 30, a semiconductor element 40, heat sinks 50 and 60, a conductive spacer 70, joint portions 80 to 82, and an external connection terminal 90. The semiconductor device 20 further includes a bonding wire 97 and a solder 100. The semiconductor device 20 constitutes the upper-lower arm circuit 9 for one phase described above.

The sealing body 30 seals part of other elements constituting the semiconductor device 20. The remaining part of the other elements is exposed to the outside of the sealing body 30. The sealing body 30 includes, for example, a resin. An example of the resin is epoxy resin. The sealing body 30 is molded by, for example, a transfer molding method using resin as a material. Such a sealing body 30 may be referred to as a sealing resin body, a molded resin, a resin molded body, or the like. The sealing body 30 may be formed using, for example, gel. The gel is, for example, filled or placed in a facing region between the heat sinks 50 and 60.

As illustrated in FIGS. 2 to 4, the sealing body 30 has a substantially rectangular shape in the plan view. The sealing body 30 has, as surfaces forming an outer shell, a first surface 30a and a second surface 30b that is a back surface opposite to the first surface 30a in the Z direction. The first surface 30a and the second surface 30b are, for example, substantially flat surfaces. Further, the sealing body 30 has side surfaces 30c, 30d, 30e and 30f connecting between the first surface 30a and the second surface 30b. The side surface 30c is a surface from which main terminals 91 to 93 of the external connection terminal 90 protrude. The side surface 30d is a surface opposite to the side surface 30c in the Y direction. The side surface 30d is a surface from which signal terminals 94 protrude. The side surfaces 30e and 30f are surfaces from which the external connection terminal 90 does not protrude. The side surface 30e is the surface opposite to the side surface 30f in the X direction.

The semiconductor element 40 includes a semiconductor substrate 41, an emitter electrode 42, a collector electrode 43, and a pad 44. The semiconductor element 40 will be also referred to as a semiconductor chip. The semiconductor substrate 41 is made of a material such as silicon (Si) or a wide band gap semiconductor having a wider band gap than silicon, and has a vertical element formed therein. Examples of the wide band gap semiconductor include silicon carbide (SiC), gallium nitride (GaN), gallium oxide (Ga₂O₃) and diamond.

The vertical element is configured to allow a main current to flow therein in the thickness direction of the semiconductor substrate 41 (semiconductor element 40), that is, in the Z direction. In the present embodiment, the vertical element includes an IGBT 11 and a diode 12 that constitute one arm. The vertical element is the IGBT with the diode 12 connected in anti-parallel, that is, a reverse conducting (RC)-IGBT. The vertical element is a heat generating element that generates heat when electricity is applied. The semiconductor substrate 41 is formed with a gate electrode (not shown). The gate electrode has, for example, a trench structure.

The semiconductor substrate 41 has a substantially rectangular shape in the plan view. The emitter electrode 42, which is one of the main electrodes, is disposed on a first surface of the semiconductor substrate 41. The collector electrode 43, which is the other of the main electrodes, is disposed on a second surface of the semiconductor substrate 41. The first surface of the semiconductor substrate 41 is one of the main surfaces of the semiconductor substrate 41 that is adjacent to the first surface 30a of the sealing body 30 in the thickness direction. The second surface of the semiconductor substrate 41 is another one of the main surfaces of the semiconductor substrate 41 that is adjacent to the second surface 30b of the sealing body 30 in the thickness direction. The second surface of the semiconductor substrate 41 is opposite to the first surface of the semiconductor substrate 41 in the thickness direction, and corresponds to a back surface of the semiconductor substrate 41.

When the IGBT 11 is turned on, a current (main current) flows between the main electrodes, that is, between the emitter electrode 42 and the collector electrode 43. The emitter electrode 42 also serves as an anode electrode of the diode 12. The collector electrode 43 also serves as a cathode electrode of the diode 12. The collector electrode 43 is formed over almost the entire second surface of the semiconductor substrate 41. The emitter electrode 42 is formed at a part on the first surface of the semiconductor substrate 41. That is, in the plan view, the collector electrode 43 has a larger area than the emitter electrode 42. The emitter electrode 42 corresponds to an upper electrode, and the collector electrode 43 corresponds to a lower electrode.

The emitter electrode 42 has a nickel (Ni) layer made of a material containing Ni as a main component. The emitter electrode 42 of the present embodiment has an aluminum (Al) layer made of a material containing Al as a main component, and the Ni layer laminated on the Al layer. Similar to the emitter electrode 42, the collector electrode 43 also has an Al layer and a Ni layer.

The pad 44 is provided as a signal electrode. The pad 44 is formed on the first surface of the semiconductor substrate 41 in a region different from a region in which the emitter electrode 42 is formed. The pad 44 is formed at an end which is on a side opposite to the region in which the emitter electrode 42 is formed in the Y direction. The pad 44 is disposed alongside the emitter electrode 42 in the Y direction. The number of the pad 44 is not particularly limited. The pad 44 includes at least a pad for a gate electrode.

As an example, the semiconductor element 40 has five pads 44. Specifically, the five pads 44 include the pad for the gate electrode, a pad for detecting an emitter potential, a pad for detecting a cathode potential of a temperature sensing diode (not shown) provided in the semiconductor element 40, a pad for detecting an anode potential, and a pad for sensing a current. The five pads 44 are aligned in the X direction.

The semiconductor device 20 includes two semiconductor elements 40. Specifically, the semiconductor device 20 includes a semiconductor element 40H that constitutes the upper arm 9H, and a semiconductor element 40L that constitutes the lower arm 9L. The semiconductor element 40H will be also referred to as a first semiconductor element, an upper arm element, or the like. The semiconductor element 40L will be also referred to as a second semiconductor element, a lower arm element, or the like. The semiconductor elements 40H and 40L have the same specifications. In other words, the semiconductor elements 40H and 40L are common members. The semiconductor elements 40H and 40L are aligned in the X direction. The semiconductor elements 40H and 40L are arranged at substantially the same position in the Z direction. The semiconductor elements 40H and 40L are arranged so that their respective surfaces, i.e., their respective emitter electrodes 42, are located on the same side in the Z direction.

The heat sink 50 is electrically connected to the emitter electrode 42 and provides a wiring function. Similarly, the heat sink 60 is electrically connected to the collector electrode 43 and provides a wiring function. The heat sinks 50 and 60 each provide a heat dissipation function for dissipating heat generated by the semiconductor element 40. For this reason, the heat sinks 50 and 60 will be also referred to as wiring members, conductive members, heat dissipation members, or the like. The heat sinks 50 and 60 are disposed so as to sandwich the semiconductor element 40 therebetween in the Z direction. The heat sinks 50 and 60 are disposed so that at least portions of the heat sinks 50 and 60 face each in the Z direction. The heat sinks 50 and 60 encompass the semiconductor element 40 in the plan view.

The heat sinks 50 and 60 are metal plates made of a metal with favorable electrical conductivity, such as Cu or a Cu alloy. The metal plate is provided, for example, as a part of a lead frame. The heat sinks 50 and 60 each have a Ni layer formed on the surface thereof by plating or the like. The heat sinks 50 and 60 each have the Ni layer at least on a solder joined surface joined with solder.

Instead of the heat sinks 50 and 60, a substrate having an insulating base member made of such as ceramic or resin and metal bodies on both sides of the insulating base member may be used as the wiring member. In this case, the metal body disposed on the semiconductor element 40 side corresponds to a conductor to be joined with the solder, that is, an upper conductor or a lower conductor. The metal body disposed on the semiconductor element 40 side has the Ni layer on its surface.

The heat sink 50 has a facing surface 50a which is a surface on the semiconductor 40 side, and a rear surface 50b opposite to the facing surface 50a. Similarly, the heat sink 60 also has a facing surface 60a and a rear surface 60b. The rear surfaces 50b and 60b of the heat sinks 50 and 60 are exposed from the sealing body 30. The rear surfaces 50b and 60b will be also referred to as heat dissipation surfaces, exposed surfaces, or the like. The rear surface 50b of the heat sink 50 is substantially flush with the first surface 30a of the sealing body 30. The rear surface 60b of the heat sink 60 is substantially flush with the second surface 30b of the sealing body 30.

The semiconductor device 20 includes two heat sinks 50. Specifically, the semiconductor device 10 includes a heat sink 50H constituting the upper arm 9H, and a heat sink 50L constituting the lower arm 9L. The heat sink 50H corresponds to a first body portion of a first upper conductor, and the heat sink 50L corresponds to a second body portion of a second upper conductor.

As shown in FIG. 5, the heat sinks 50H and 50L each have a substantially rectangular shape in the plan view. The heat sinks 50H and 50L are aligned in the X direction. As shown in FIGS. 3 and 4, the heat sinks 50H and 50L have substantially the same thickness and are disposed at substantially the same position in the Z direction. The heat sinks 50H and 50L each encompass the corresponding semiconductor element 40 and conductive spacer 70 therein in the plan view. The heat sinks 50H and 50L each have a groove 51 for accommodating overflowing solder on the facing surface 50a. The groove 51 surrounds the solder joined portion on the facing surface 50a. The groove 51 is formed in, for example, a loop shape. The rear surfaces 50b of the heat sinks 50H and 50L exposed from the sealing body 30 are aligned in the X direction.

The semiconductor device 20 includes two heat sinks 60. Specifically, the semiconductor device 20 includes a heat sink 60H constituting the upper arm 9H, and a heat sink 60L constituting the lower arm 9L. The heat sink 60H corresponds to a first lower conductor, and the heat sink 60L corresponds to a second lower conductor.

As shown in FIG. 6, the heat sinks 60H and 60L each have a substantially rectangular shape in the plan view. The heat sinks 60H and 60L are aligned in the X direction. As shown in FIGS. 3 and 4, the heat sinks 60H and 60L have substantially the same thickness and are disposed at substantially the same position in the Z direction. The heat sinks 60H and 60L each encompass the corresponding semiconductor element 40 in the plan view. The rear surfaces 60b of the heat sinks 60H and 60L exposed from the sealing body 30 are aligned in the X direction.

The conductive spacer 70 is interposed between the semiconductor element 40 and the heat sink 50 in the Z direction. The conductive spacer 70 provides a spacer function for ensuring a predetermined distance between the semiconductor element 40 and the heat sink 50. For example, the conductive spacer 70 secures a height for electrically connecting the signal terminal 94 to the corresponding pad 44 of the semiconductor element 40. The conductive spacer 70 is located on an electrical and thermal conductive path between the emitter electrode 42 of the semiconductor element 40 and the heat sink 50, and provides a wiring function and a heat dissipation function. The conductive spacer 70 together with the heat sink 50 constitutes the upper conductor.

The conductive spacer 70 is a metal member made of a metal, such as Cu, that has favorable electrical and thermal conductivity. The conductive spacer 70 will be also referred to as a terminal, a terminal block, a metal block, or the like. The conductive spacer 70 has a Ni layer formed on the surface thereof by plating or the like. The conductive spacer 70 has the Ni layer at least on a solder joined surface joined with solder. The conductive spacer 70 of the present embodiment is a columnar body having a substantially rectangular shape in the plan view and having substantially the same size as the emitter electrode 42.

The semiconductor device 20 includes two conductive spacers 70. Specifically, the semiconductor device 20 includes a conductive spacer 70H constituting the upper arm 9H and a conductive spacer 70L constituting the lower arm 9L. The conductive spacer 70H corresponds to a first spacer portion of the first upper conductor, and the conductive spacer 70L corresponds to a second spacer portion of the second upper conductor.

The joint portions 80 to 82 connects between elements constituting the upper-lower arm circuit 9. The joint portions 80 to 82 connect between the elements constituting the semiconductor device 20. The joint portions 80 to 82 are metal members made of a metal, such as Cu, that has favorable electrical and thermal conductivity. The joint portions 80 to 82 each have a Ni layer formed on the surface thereof by plating or the like. The joint portions 80 to 82 each have the Ni layer at least on a solder joined surface joined with solder.

As shown in FIGS. 3 and 6, the joint portion 80 connects to the heat sink 60L. The thickness of the joint portion 80 is smaller than the thickness of the heat sink 60L. The joint portion 80 connects to a surface (side surface) of the heat sink 60L, which faces the heat sink 60H, in a state of being flush with the facing surface 60a of the heat sink 60L. The joint portion 80 has two bent portions to have a substantially crank-shape on the ZX plane. The joint portion 80 is covered by the sealing body 30.

The joint portion 80 may be connected to the heat sink 60L by being provided continuously and integrally with the heat sink 60L, or may be provided as a separate member and connected to the heat sink 60L by joining. The joint portion 80 of the present embodiment is provided integrally with the heat sink 60L as a part of a lead frame. The Ni layer is provided continuously and integrally over the heat sink 60L and the joint portion 80.

As shown in FIGS. 3, 4 and 5, the joint portions 81 and 82 each connects to the corresponding heat sink 50. The joint portion 81 connects to the heat sink 50H. The joint portion 82 connects to the heat sink 50L. The joint portions 81 and 82 each have the thickness smaller than the thickness of the corresponding heat sink 50. The joint portions 81 and 82 are covered by the sealing body 30.

The joint portions 81 and 82 may be connected to the corresponding heat sinks 50 by being provided continuously and integrally with the corresponding heat sinks 50, or may be provided as separate members and connected to the corresponding heat sinks 50 by joining. The joint portions 81 and 82 of the present embodiment are provided integrally with the corresponding heat sinks 50H and 50L. The joint portions 81 and 82 extend in the X direction from the side surfaces of the heat sinks 50H and 50L, which face each other. The Ni layer is provided continuously and integrally over the heat sink 50H and the joint portion 81. The Ni layer is provided continuously and integrally over the heat sink 50L and the joint portion 82.

As an example, the heat sink 50H including the joint portion 81 and the heat sink 50L including the joint portion 82 are common members. The arrangement of the heat sink 50H having the joint portion 81 and the arrangement of the heat sink 50L having the joint portion 82 are two-fold symmetrical about the Z-axis as the rotation axis. Solder is interposed between a surface of the joint portion 80 and a surface of the joint portion 81, which face each other, to form a solder joined portion. As shown in FIG. 5, the joint portions 81 and 82 are disposed in an area between the heat sinks 50H and 50L in the plan view. The joint portions 81 and 82 are aligned in the Y direction in the area between the heat sinks 50H and 50L.

A groove 83 for accommodating overflowing solder therein is formed on a joining surface of each of the joint portions 81 and 82. The groove 83 is formed into a loop shape so as to surround the solder joined portion. The groove 83 is formed by, for example, press working. The joint portions 80 and 81 each correspond to a joint conductor and a first joint conductor. The joint portion 82 corresponds to a second joint conductor.

The external connection terminal 90 is a terminal for electrically connecting the semiconductor device 20 to an external device. The external connection terminal 90 is formed using a metal material having favorable conductivity, such as copper. The external connection terminal 90 is, for example, a plate member. The external connection terminal 90 will be also referred to as a “lead”. The external connection terminal 90 includes main terminals 91, 92, and 93 and a signal terminal 94. The main terminals 91, 92, and 93 are external connection terminals 90 electrically connected to the main electrodes of the semiconductor element 40.

As shown in FIGS. 5 and 6, the main terminal 91 is electrically connected to the collector electrode 43 of the semiconductor element 40H. The main terminal 91 is electrically connected to the positive terminal of the smoothing capacitor 5. The main terminal 91 will be also referred to as a P terminal, a high potential power supply terminal, or the like. The main terminal 91 is connected to the collector electrode 43 of the semiconductor element 40H via the heat sink 60H. The main terminal 91 connects to one end of the heat sink 60H in the Y direction. The thickness of the main terminal 91 is smaller than the thickness of the heat sink 60H. The main terminal 91 is connected to the heat sink 60H so as to be substantially flush with the facing surface 60a, for example. The main terminal 91 may be connected to the heat sink 60H by being provided integrally and continuously with the heat sink 60H, or may be provided as a separate member and connected to the heat sink 60H by joining.

In the present embodiment, the main terminal 91 is provided integrally with the heat sink 60H as a part of the lead frame. The main terminal 91 extends in the Y direction from the heat sink 60H and protrudes to the outside from the side surface 30c of the sealing body 30. The main terminal 91 has a bent portion at a part covered by the sealing body 30, and protrudes from the side surface 30c at a position near the center in the Z direction.

As shown in FIGS. 5 and 6, the main terminal 92 is electrically connected to the emitter electrode 42 of the semiconductor element 40L. The main terminal 92 is electrically connected to the negative terminal of the smoothing capacitor 5. The main terminal 92 will be also referred to as an N terminal, a low potential power supply terminal, or the like. The main terminal 92 is connected to the emitter electrode 42 of the semiconductor element 40L via the joint portion 82, the heat sink 50L, and the conductive spacer 70L. The main terminal 92 extends in the Y direction and protrudes to the outside of the sealing body 30 from the same side surface 30c as the main terminal 91.

The main terminal 92 has a connection portion 920 for connection with the joint portion 82 near one end in the Y direction. A portion of the main terminal 92 including the connection portion 920 is covered by the sealing body 30, and the remaining portion of the main terminal 92 protrudes from the sealing body 30. The connection portion 920 has a thickness greater than the thickness of the portion of the main terminal 92 protruding from the sealing body 30. The thickness of the connection portion 920 is, for example, approximately the same as the thickness of the heat sink 50L. Similar to the main terminal 91, the main terminal 92 also has a bent portion and protrudes from the side surface 30c at a position near the center in the Z direction. The main terminal 92 has a Ni layer formed on the surface thereof by plating or the like. The main terminal 92 has the Ni layer at least on a solder joined surface of the connection portion 920.

The main terminal 93 is connected to the connection point between the upper arm 9H and the lower arm 9L. The main terminal 93 is electrically connected to the emitter electrode 42 of the semiconductor element 40H and the collector electrode 43 of the semiconductor element 40L. The main terminal 93 is electrically connected to the winding 3a of the corresponding phase of the motor generator 3. The main terminal 93 will be also referred to as an output terminal, an AC terminal, an O terminal, or the like. The main terminal 93 is electrically connected to the emitter electrode 42 of the semiconductor element 40H via the heat sink 60L, the joint portions 80 and 81, the heat sink 50H, and the conductive spacer 70H. The main terminal 93 is connected to the collector electrode 43 of the semiconductor element 40L via the heat sink 60L.

The main terminal 93 connects to one end of the heat sink 60L in the Y direction. The thickness of the main terminal 93 is smaller than the thickness of the heat sink 60L. The main terminal 93 connects to the heat sink 60L so as to be substantially flush with the facing surface 60a, for example. The main terminal 93 may be connected to the heat sink 60L by being provided integrally and continuously with the heat sink 60L, or may be provided as a separate member and connected to the heat sink 60L by joining.

In the present embodiment, the main terminal 93 is provided integrally with the heat sink 60L as a part of the lead frame. The main terminal 93 extends in the Y direction from the heat sink 60L, and protrudes to the outside of the sealing body 30 from the same side surface 30c as the main terminal 91. Similar to the main terminal 91, the main terminal 93 also has a bent portion and protrudes from the side surface 30c at a position near the center in the Z direction. The three main terminals 91 to 93 are arranged side by side in the X direction in an order of the main terminal 91, the main terminal 92, and the main terminal 93.

The signal terminal 94 is electrically connected to the corresponding pad 44 of the semiconductor element 40. In the present embodiment, the signal terminal 94 is electrically connected to the pad 44 via a bonding wire 97. The signal terminal 94 extends in the Y direction and protrudes to the outside from the side surface 30d of the sealing body 30. The semiconductor device 20 has five signal terminals 94 for each semiconductor element 40, and thus has ten signal terminals 94 in total. The signal terminals 94 are arranged side by side in the X direction. The signal terminals 94 are formed on, for example, a lead frame common to the heat sink 60 and the main terminals 91 to 93.

The semiconductor device 20 includes a hanging lead 95. The heat sink 60 (60H, 60L), the joint portion 81, the main terminals 91 to 93, and the signal terminals 94 are provided by a lead frame as a common member. The lead frame is a profile strip having a thickness that varies in parts. Before being cut, the signal terminals 94 are supported by the hanging lead 95 via tie bars (not shown). Unnecessary portions of the lead frame, such as the tie bars and a peripheral frame, are cut (removed) after the sealing body 30 is molded.

The semiconductor device 20 includes multiple solders 100 for connecting the elements. The solders 100 include solders 101H, 101L, 102H, 102L, 103H, 103L, 104, and 105. The solder 101H is interposed between the emitter electrode 42 of the semiconductor element 40H and the conductive spacer 70H, and joins the emitter electrode 42 and the conductive spacer 70H to each other. The solder 102H is interposed between the conductive spacer 70H and the heat sink 50H, and joins the conductive spacer 70H and the heat sink 50H to each other. The solder 101H and the solder 102H correspond to first upper solders. The solder 103H is interposed between the collector electrode 43 of the semiconductor element 40H and the heat sink 60H, and joins the collector electrode 43 and the heat sink 60H to each other. The solder 103H corresponds to a first lower solder.

The solder 101L is interposed between the emitter electrode 42 of the semiconductor element 40L and the conductive spacer 70L, and joins the emitter electrode 42 and the conductive spacer 70L to each other. The solder 102L is interposed between the conductive spacer 70L and the heat sink 50L, and joins the conductive spacer 70L and the heat sink 50L to each other. The solder 101L and the solder 102L correspond to the second upper solders. The solder 103L is interposed between the collector electrode 43 of the semiconductor element 40L and the heat sink 60L, and joins the collector electrode 43 and the heat sink 60L. The solder 103L corresponds to a second lower solder.

The solders 101H and 101L will be also referred to as on-element solders. The solders 102H and 102L will be also referred to as on-spacer solders. The solders 103H and 103L will be also referred to as under-element solders.

The solder 104 electrically connects the heat sink 50H and the heat sink 60L to each other, together with the joint portions 80 and 81. In the present embodiment, the solder 104 is interposed between the joint portion 80 connecting to the heat sink 60L and the joint portion 81 connecting to the heat sink 50H, and joins the joint portion 80 and the joint portion 81 to each other. The solder 104 corresponds to a relay solder, or a first relay solder. The solder 105 electrically connects the heat sink 50L and the main terminal 92 to each other, together with the joint portion 82. In the present embodiment, the solder 105 is interposed between the joint portion 82 connecting to the heat sink 50L and the connection portion 920 of the main terminal 92, and joins the joint portion 82 and the main terminal 92 to each other. The solder 105 corresponds to a second relay solder.

The multiple solders 100 each contain copper (Cu) and tin (Sn). The solder 100 is, for example, a multi-element lead-free solder containing Cu, bismuth (Bi), antimony (Sb) or the like with the balance being Sn. The thickness of each solder 100 is, for example, about 100 μm.

As described above, in the semiconductor device 20, the multiple semiconductor elements 40 constituting the upper-lower arm circuit 9 for one phase are sealed by the sealing body 30. The sealing body 30 integrally seals the multiple semiconductor elements 40, a part of each of the heat sinks 50, a part of each of the heat sinks 60, the conductive spacer 70, the joint portions 80 to 82, the main terminals 91 to 93, and a part of each of the signal terminals 94.

The semiconductor element 40 is disposed between the heat sink 50 and the heat sink 60 in the Z direction. The semiconductor element 40 is interposed between the heat sink 50 and the heat sink 60, which are arranged to face each other. Thereby, the heat of the semiconductor element 40 can be dissipated on both sides in the Z direction. The semiconductor device 20 has a double-sided heat dissipation structure. The rear surface 50b of the heat sink 50 is substantially flush with the first surface 30a of the sealing body 30. The rear surface 60b of the heat sink 60 is substantially flush with the second surface 30b of the sealing body 30. Since the rear surfaces 50b and 60b are exposed surfaces, it is possible to enhance the heat dissipation.

In addition, a gold (Au) layer may be provided on the Ni layer described above by plating or the like. For example, Au suppresses oxidation of Ni and improves wettability with solder. Since Au diffuses into the solder during soldering, it is present in the state before joining and is not present in the joined state.

### <Output Current and Reverse Current>

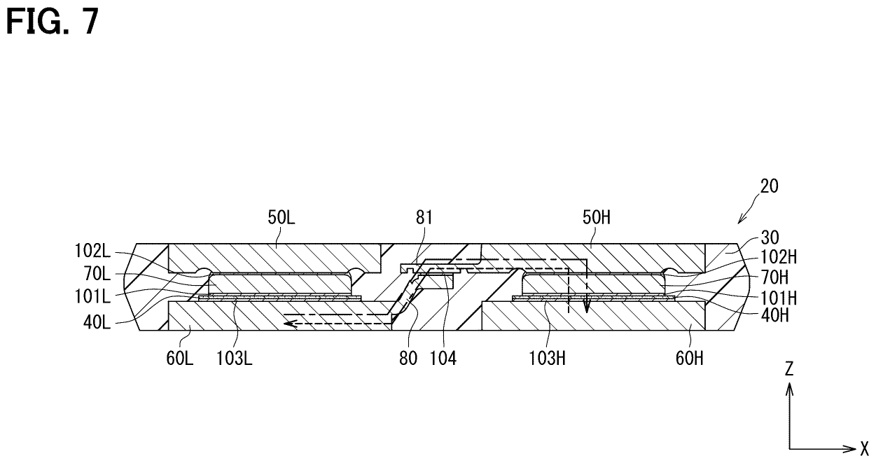

Next, an output current and a reverse current will be described with reference to FIG. 7. FIG. 7 shows, as an example, the output current and the reverse current for the semiconductor element 40H on the upper arm 9H side. In FIG. 7, the output current is indicated by a dashed arrow, and the reverse current is indicated by an alternate short and long dashed arrow.

The output current (main current) flows when the IGBT is in operation. The output current on the upper arm 9H side flows from the main terminal 91 to the motor generator 3 via the IGBT 11 of the semiconductor element 40H and the main terminal 93. Specifically, as shown by the dashed arrow in FIG. 7, the output current flows through a path of: the main terminal 91 (P terminal)→the heat sink 60H→the semiconductor element 40H (IGBT 11)→the conductive spacer 70H→the heat sink 50H→the joint portion 81→the joint portion 80→the heat sink 60L→to the main terminal 93 (O terminal).

The reverse current flows when the diode is in operation. The reverse current on the upper arm 9H side flows in the direction opposite to the output current, that is, from the main terminal 93 toward the DC power supply 2 via the diode 12 of the semiconductor element 40H and the main terminal 91. Specifically, as shown by the alternate short and long dashed arrow in FIG. 7, the reverse current flows through a path of: the main terminal 93 (O terminal)→the heat sink 60L→the joint portion 80→the joint portion 81→the heat sink 50H→the conductive spacer 70H→the semiconductor element 40H (diode 12)→the heat sink 60H→the main terminal 91 (P terminal).

The same applies to the lower arm 9L side. The output current flows through a path of: the main terminal 93→the IGBT 11 of the semiconductor element 40L→the main terminal 92. The reverse current flows through a path of: the main terminal 92→the diode 12 of the semiconductor element 40L→the main terminal 93.

### <Joining Structure and Solder Grain Size>

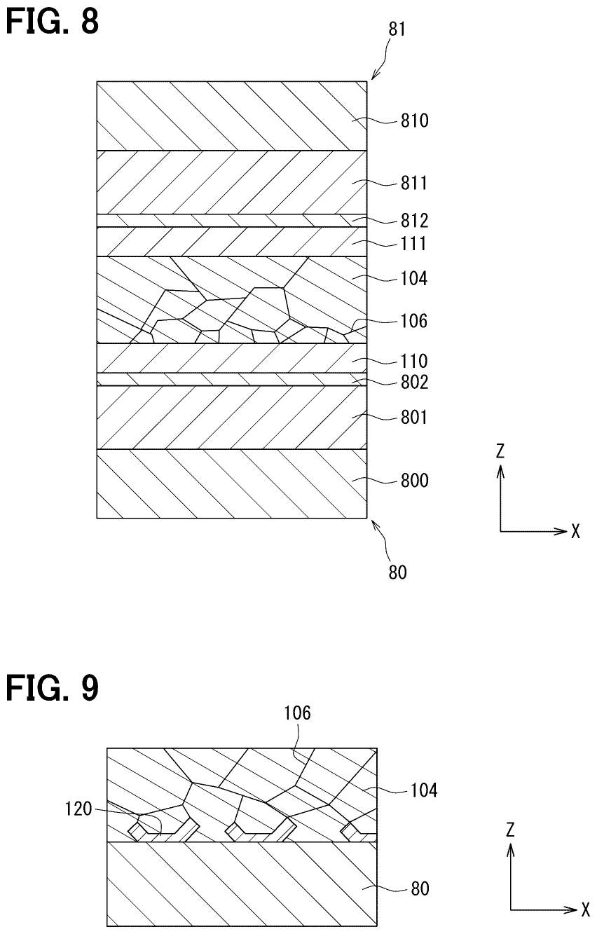

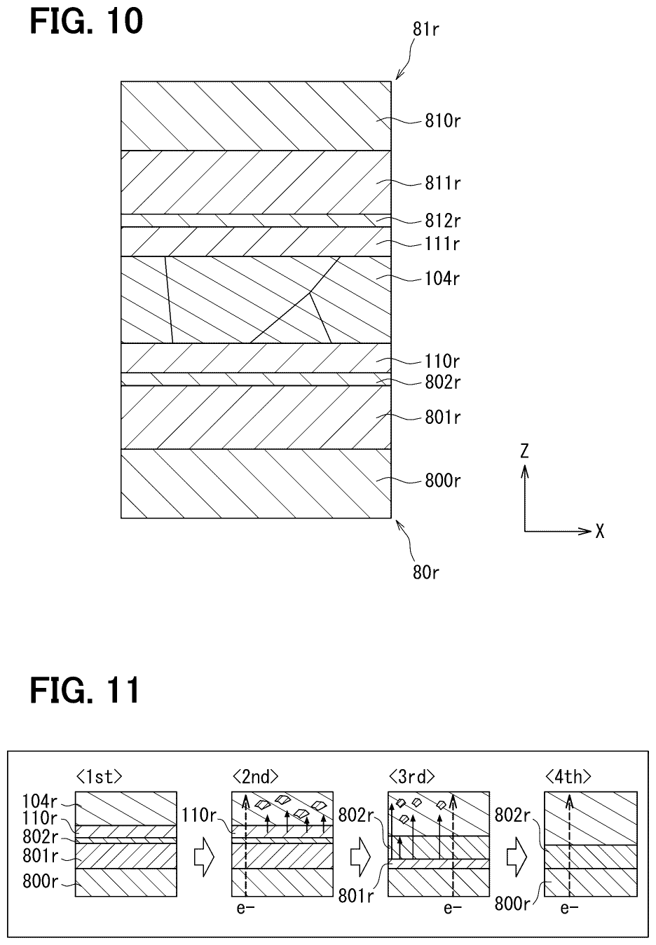

Next, the joining structure and the solder grain size will be described with reference to FIGS. 8 to 10. FIG. 8 is a cross-sectional view showing the joining structure of the joint portions 80 and 81 in the semiconductor device 20 according to the present embodiment. FIG. 8 is an enlarged cross-sectional view of a region VIII indicated by a dashed line in FIG. 3. In FIG. 8, illustration of wire pieces 120 is omitted for the sake of convenience. FIG. 9 is a cross-sectional view illustrating the wire piece 120 provided on the surface of the joint portion 80. In FIG. 9, illustration of an alloy layer 110 is omitted for the sake of convenience. FIG. 10 is a cross-sectional view illustrating a reference example. FIG. 10 corresponds to FIG. 8. In the reference example, each of components is denoted by a reference numeral with suffix “r” relative to the reference numeral of a related component of the semiconductor device 20.

As shown in FIG. 8, the joint portion 80 has a Cu-based base material 800 and a Ni layer 801 provided on the base material 800. Similarly, the joint portion 81 also has a Cu-based base material 810 and a Ni layer 811 provided on the base material 810. As an example, the Ni layers 801 and 811 are NiP films formed by electroless plating. The Ni layers 801 and 811 are Ni plating films containing phosphorous (P).

The semiconductor device 20 includes an alloy layer 110 interposed between the Ni layer 801 and the solder 104, and an alloy layer 111 interposed between the Ni layer 801 and the solder 104. The alloy layers 110 and 111 will be also referred to as intermetallic compound (IMC). The alloy layers 110 and 111 are formed during solder joining. The alloy layers 110 and 111 contain Ni, Cu, and Sn. The composition of the alloy layers 110 and 111 is, for example, (Ni—Cu)₃Sn₄.

The semiconductor device 20 further includes P-rich layers 802 and 812. The P-rich layer 802 is formed on the surface of the Ni layer 801. The P-rich layer 812 is formed on the surface of the Ni layer 811. The P-rich layers 802 and 812 are formed by diffusing a portion of Ni in the Ni layers 801 and 811 toward the solder 104 during the joining. The P-rich layers 802 and 812 are layers in which the content of P is richer than in the Ni layers 801 and 811 (NiP). The composition of the P-rich layers 802 and 812 is, for example, NisP.

As shown in FIG. 9, at least one of the joint portion 80 or 81 has multiple wire pieces 120 on the solder joined surface. The wire piece 120 is a small piece of a bonding wire. The wire piece 120 will be also referred to as a protruding portion or a stud bonding. The wire piece 120 is disposed within the solder 104. The multiple wire pieces 120 are interspersed within the solder 104. By appropriately setting the height of the wire pieces 120, it is also possible to ensure a minimum thickness of the solder 104. The multiple wire pieces 120 are fixed (joined) to a first facing surface that is one of facing surfaces of the solder joined part, and protrude toward a second facing surface that is another one of the facing surfaces. As an example, in the present embodiment, the wire pieces 120 are provided on the solder joined surface of the joint portion 80. The wire pieces 120 are provided, for example, at a predetermined pitch.

Since the wire pieces 120 are provided, the surface of the joint portion 80 has an uneven shape. The solder 104 starts to grow into grains from the wire pieces 120 at the starting points when the solder 104 solidifies. When adjacent grains collide, grain boundaries 106 are formed. The crystal grains grow from the corners of the wire piece 120, for example, from the upper corners. Therefore, the grain size of the solder 104 is smaller than, for example, the grain size of the solders 103H and 103L. As described above, the thickness of the solder 104 is about 100 μm. The grain size of the solder 104 is smaller than the thickness of the solder 104, that is, smaller than 100 μm.

In a comparative example shown in FIG. 10, no wire piece is provided on the solder joined surfaces of the joint portions 80r and 81r. In other words, the grain size of the solder 104r is not controlled. The other configurations of the comparative example are similar to those of the semiconductor device 20 of the present embodiment. In such a case, the grain size of the solder 104r is about 100 μm. The number of crystal grains of the solder 104r in the thickness direction (Z direction) of the solder 104 is about one or two.

In the present embodiment, among the multiple solders 100, the wire pieces 120 are not arranged in the solders 103H and 103L. The grain size of the solders 103H and 103L is the same as that of the comparative example shown in FIG. 10. The grain size of the solders 103H and 103L is larger than that of the solder 104 in which the wire pieces 120 are disposed.

### <EM>

Next, the electromigration (EM) will be described with reference to FIG. 11. FIG. 11 is a reference diagram showing the mechanism of EM progression. Also in FIG. 11, the reference numerals of the elements are denoted with the suffix r to reference numerals of the related elements of the semiconductor device 20. In the example shown in the reference diagram, similar to the configuration shown in FIG. 10, the grain size of the solder 104r is not controlled. The other configurations are similar to those of the semiconductor device 20 of the present embodiment.

In FIG. 11, a 1st stage shows an initial stage before the electricity is applied. An alloy layer 110r is present between a Ni layer 801r and a solder 104r. In addition, a P-rich layer 802r is formed on the surface of the Ni layer 801r.

In FIG. 11, a 2nd stage, a 3rd stage and a 4th stage show stages when the output current is applied. A dashed arrow indicates a flow direction of electron (e). As shown in the 2nd stage in FIG. 11, Cu and other elements in the alloy layer 110r migrate (diffuse) toward the joint portion 81r in accordance with the movement of electrons. Specifically, metals such as Cu are ionized and moved toward the joint portion 81r. As a result, the alloy layer 110r gradually becomes thinner and disappears as shown in the 3rd stage in FIG. 11.

When the alloy layer 110r disappears, as shown in the 3rd sage in FIG. 11, Ni in the Ni layer 801r moves (diffuses) toward the joint portion 81r in accordance with the movement of electrons. Thus, the Ni layer 801r decreases, and the P-rich layer 802r increases. Then, as shown in the 4th stage in FIG. 11, the Ni layer 801r disappears, and the P-rich layer 802r reaches the base material 800r. That is, the P-rich layer 802r is replaced with the Ni layer 801r.

After the P-rich layer 802r reaches the base material 800r, when the time further elapses, the adhesion decreases and, for example, voids are generated. Further, cracks are generated along the interface from the voids as the starting points. Furthermore, cracks may also occur in the P-rich layer 802r.

As described above, in the configuration where the solder grain size is not controlled (see FIG. 10), the grain size of the solder 104r is large. There are few grain boundaries in the movement path of Cu. Therefore, Cu in the alloy layer 110r is likely to move along with the movement of electrons.

Although an example of the output current has been illustrated, the same applies to the case of a reverse current. When the reverse current is applied, first, the alloy layer 111r on the joint portion 81r side disappears, and then the P-rich layer 812r is replaced with the Ni layer 811r. After the P-rich layer 812r reaches the base material 810r, when the time further elapses, the adhesion decreases, and for example, voids and cracks occur. Since the grain size of the solder 104r is large, Cu in the alloy layer 111r is likely to move with the movement of electrons.

On the other hand, in the configuration of the present embodiment (see FIG. 8), the grain size of the solder 104 at the joint portions 80 and 81 where the current density is high is smaller than the grain size of the solder 103H and 103L that is not controlled. Therefore, Cu in the alloy layers 110 and 111 is less likely to move in association with the movement of electrons. In other words, the alloy layers 110 and 111 are less likely to disappear. The time required for the alloy layers 110 and 111 to disappear increases. This delays the time when the Ni layers 801 and 811 become the P-rich layers 802 and 812 and start to decrease. The time required for the Ni layers 801 and 811 to disappear increases.

### Summary of First Embodiment

In the plan view, the area of the collector electrode 43, which is the main electrode on the high potential side, is larger than the area of the emitter electrode 42, which is the main electrode on the low potential side. Further, in order to reduce the semiconductor device 20 in size, it is difficult to ensure the areas of the solder joined portions of the joint portions 80 and 81 and the solder joined portion of the joint portion 82 to be large. As a result, in the semiconductor device 20 constituting the upper-lower arm circuit 9 for one phase, the current densities in the solders 101H, 101L, 102H, 102L, 104, and 105 are higher than the current densities in the solders 103H and 103L. In other words, among the multiple solders 100, the EM is likely to progress in the joined portions of the solders 101H, 101L, 102H, 102L, 104, and 105. Among the multiple solders 100, the EM is less likely to progress in the joined portions of the solders 103H and 103L.

As an example, in the present embodiment, the grain size of the solder 104 (relay solder, first relay solder) is smaller than the grain size of the solders 103H and 103L (first lower solder and second lower solder). The solder 104 has more grain boundaries 106 between the connection targets. The grain boundaries 106 hinder the movement of Cu. Therefore, Cu in the alloy layers 110 and 111 is less likely to move in accordance with the movement of electrons. As such, the time required for the alloy layers 110 and 111 to disappear can be extended. In addition, the time required for the Ni layers 801 and 811 to disappear can be increased. As a result, the EM lifetime can be improved.

The current density of the semiconductor device 20, that is, the current density of the current path connecting to the main electrode, is maximum at the solder joined portions of the joint portions 80 and 81, for example. In the present embodiment, the grain size of the solder 104 is made small, so that the EM lifetime can be improved.

The effect of the grain size of the solder 104 was confirmed through prototypes. It was confirmed that, by reducing the grain size of the solder 104, the disappearance of the alloy layers 110 and 111 is delayed, that is, the progression of EM can be slowed down. In this time, the Ni layers 801 and 811 were formed by electroless NiP plating. The composition of the alloy layers 110 and 111 was (Ni—Cu)₃Sn₄.

In the present embodiment, the joint portion 80 has the multiple wire pieces 120 on the solder joined surface. The solder 104 solidifies from the wire pieces 120 as the starting points. The wire piece 120 serves as the starting point for solidification. By providing the wire pieces 120, the grain size of the solder 104 can be reduced, improving the EM lifetime.

### Modification

Although an example in which the wire pieces 120 are provided on the joint portion 80 has been illustrated, the present disclosure is not limited to this example. The wire pieces 120 may be provided on the solder joined surface of the joint portion 81. This also causes the solder 104 to solidify and become smaller grains, starting from the wire pieces 120. The wire pieces 120 may be provided om each of the joint portions 80 and 81. In other words, it is sufficient to provide the wire pieces 120 on at least one of the connection targets.

Although the solder 104 is shown as an example of a solder having small grain size, the present disclosure is not limited to this example. As the small grain size solder, at least one of the solders 100, other than the solders 103H and 103L, can be used.

For example, the solder 105 may be configured as the small grain size solder. By providing multiple wire pieces 120 on the solder joined surfaces of the joint portion 82 and/or the connection portion 920 of the main terminal 92, the grain size of the solder 105 can be made smaller than the grain size of the solders 103H and 103L. In this case, it is possible to suppress the progression of EM at the joined portion of the solder 105.

For example, the solders 101H and 101L may be configured as the small grain size solder. By providing the multiple wire pieces 120 on the solder joined surfaces of the emitter electrode 42 and/or the conductive spacer 70, the grain size of the solders 101H and 101L can be made smaller than the grain size of the solders 103H and 103L. In this case, it is possible to suppress the progression of EM at the joined portions of the solders 101H and 101L. This is effective in reducing the semiconductor element 40 in size.

For example, the solders 102H and 102L may be configured as the small grain size solder. By providing the multiple wire pieces 120 on the solder joined surfaces of the conductive spacer 70 and/or heat sink 50, the grain size of the solders 102H and 102L can be made smaller than the grain size of the solders 103H and 103L. In this case, it is possible to suppress the progression of EM at the joined portions of the solders 102H and 102L. This is effective in reducing the size of the semiconductor element 40, similar to the reduction in the grain size of the solders 101H and 101L.

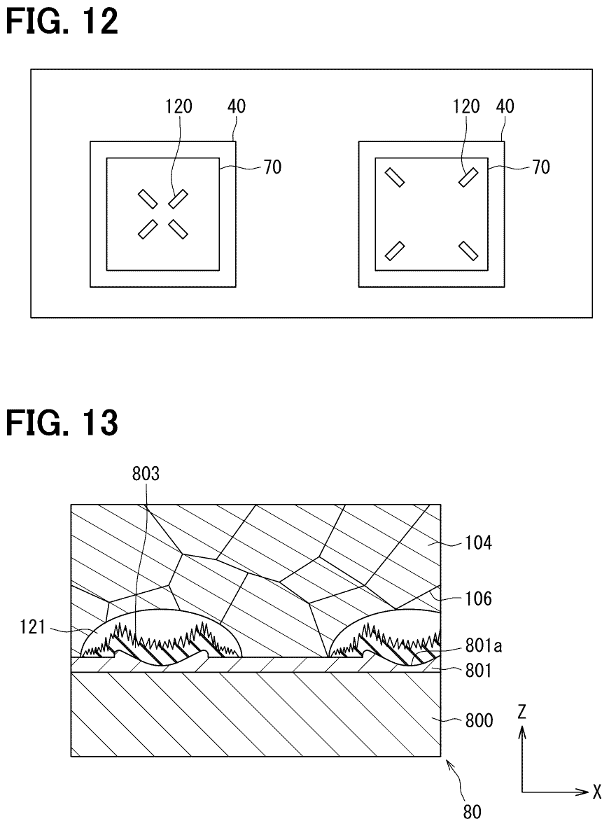

The arrangement of the multiple wire pieces 120 is not particularly limited. For example, as shown in FIG. 12, the multiple wire pieces 120 may be provided on the solder joined surface of the conductive spacer 70 in a portion that overlaps with the vicinity of the center of the semiconductor element 40. The EM progresses more with the increase in the temperature and the increase in the current density. By providing the wire pieces 120 in the area corresponding to the vicinity of the center of the semiconductor element 40 in the plan view, it is possible to reliably reduce the grain size in the portion where the temperature becomes high. Therefore, the progression of EM can be suppressed. The multiple wire pieces 120 may be provided on the solder joined surface of the conductive spacer 70 at portions that correspond to the four corners of the emitter electrode 42. The temperature is likely to be low and the solder is more likely to be solidified at the four corners. Therefore, the grain size reduction can be enhanced.

The arrangement of the wire pieces 120 shown in FIG. 12 is not limited on the conductive spacer 70. The wire pieces 120 may be arranged near the center of the element or at four corners on the emitter electrode 42. The wire pieces 120 may be arranged in an area corresponding to the vicinity of the center of the element or in areas corresponding to the four corners on the heat sink 50.

An example in which the semiconductor device 20 includes the conductive spacer 70 has been illustrated, but the present disclosure is not limited to this example. Instead of the conductive spacer 70, the heat sink 50 may be provided with a protrusion that provides a function of the spacer. In this case, the heat sink 50 corresponds to the upper conductor. The upper solder is interposed between the emitter electrode 42 and the heat sink 50 to join the emitter electrode 42 and the heat sink 50 to each other. The multiple wire pieces 120 may be provided on the solder joined surface of the emitter electrode 42 and/or the heat sink 50 to make the upper solder fine grain.

An example in which the semiconductor device 20 includes the joint portion 82 has been illustrated. However, the present disclosure is not limited to this example. The heat sink 50L, the joint portion 82, and the main terminal 92 may be provided as a continuous and integral member. In other words, the semiconductor device 20 may not include the solder 105.

An example in which the semiconductor device 20 has two joint portions 80 and 81 to connect the upper arm 9H and the lower arm 9L has been illustrated. However, the present disclosure is not limited to this example. The semiconductor device 20 may have one of the joint portion 80 or the joint portion 81. For example, the semiconductor device 20 may be configured to have only the joint portion 80 that is connected to the heat sink 50H through the solder 104, without having the joint portion 81. As another example, the semiconductor device 20 may be configured to have only the joint portion 81 that is connected to the heat sink 60L through the solder 104, without having the joint portion 80.

### Second Embodiment

The present embodiment is a modification of the preceding embodiment(s) as a basic configuration and may incorporate description of the preceding embodiment(s). In the preceding embodiment, multiple wire pieces are provided as the starting points for solidification. In place of the wire pieces, an uneven oxide film formed by laser irradiation may be provided.

### <Uneven Oxide Film>

FIG. 13 is a cross-sectional view illustrating an uneven oxide film 803 provided on the surface of the joint portion 80 in a semiconductor device 20 according to the present embodiment. FIG. 13 corresponds to FIG. 9. For convenience, illustrations of the P-rich layer 802 and the alloy layer 110 are omitted in FIG. 13.

As described above, the joint portion 80 has the base material 800 and the Ni layer 801 disposed on the surface of the base material 800. As shown in FIG. 13, the joint portion 80 further has the uneven oxide film 803 on the Ni layer 801. The uneven oxide film 803 is formed in multiple locations on the solder joined surface of the joint portion 80 by irradiating the Ni layer 801 with a laser light.

The uneven oxide film 803 is an oxide film made of Ni as a main component. In the present embodiment, Ni₂O₃, NiO, and Ni constitute 80%, 10%, and 10%, respectively, of the uneven oxide film 803.

Recesses 801a on the surface of the Ni layer 801 are formed by irradiation with a pulsed laser beam. One recess 801a is formed by each pulse. The uneven oxide film 803 is formed by melting, vaporizing, and depositing a surface portion of the Ni layer 801 by irradiation with the laser beam. The uneven oxide film 803 is an oxide film derived from the Ni layer 801. The uneven oxide film 803 is a film of oxide of the metal (Ni) that is the main component of the Ni layer 801. The uneven oxide film 803 is formed following the unevenness of the surface of the Ni layer 801 having the recesses 801a. On the surface of the uneven oxide film 803, unevenness is formed at a pitch finer than the width of the recesses 801a. In other words, the extremely fine recesses and protrusions (a roughened portion) are formed.

The pulsed laser beam is adjusted to have the energy density larger than 0 J/cm² and equal to or smaller than 100 J/cm² and the pulsed width equal to or less than 1 microsecond. A YAG laser, a YVO₄ laser, a fiber laser, or the like can be used to satisfy this condition. For example, in the case of a YAG laser, the energy density may be 1 J/cm² or more. In a case where the Ni layer 801 is an electroless Ni plating, the Ni layer 801 can be processed even when the energy density is, for example, about 5 J/cm².

### <Void>

The oxide film (the uneven oxide film 803) has lower wettability with solder, as compared with a metal film. Since the uneven oxide film 803 has fine protrusions and recesses on the surface, the contact area with the solder is reduced and a part of the solder is formed into a spherical shape due to surface tension. That is, the contact angle becomes large and the wettability with the solder becomes low.

As described above, the uneven oxide film 803 has low wettability with respect to the solder 104. Therefore, as shown in FIG. 13, a void 121 is formed so as to cover the uneven oxide film 803. The void 121 is formed on a periphery of the uneven oxide film 803. In the semiconductor device 20, multiple voids 121 exist in the vicinity of the solder joined surface of the joint portion 80. The other configurations of the second embodiment are similar to the configurations described in the preceding embodiment(s).

### Summary of Second Embodiment

According to the configuration of the present embodiment described above, it is possible to achieve the similar effects to the configurations of the preceding embodiment(s) described above. Specifically, multiple voids 121 caused by the uneven oxide film 803 are present within the solder 104. When the solder 104 solidifies, grains grow from the voids 121 as the starting points. The voids 121 serves as the starting points of solidification. By providing the uneven oxide film 803 and thus the voids 121, the grain size of the solder 104 can be made smaller than the grain size of the solders 103H and 103L, thereby improving the EM lifetime.

### Modification

Although an example in which the uneven oxide film 803 is provided on the joint portion 80 has been illustrated, the present disclosure is not limited to this example. The uneven oxide film 803 can be provided on conductors excluding the heat sink 60, of the conductors of the connection targets. For example, an uneven oxide film may be provided on the solder joined surface of the joint portion 81. An uneven oxide film may be provided on each of the joint portions 80 and 81. An uneven oxide film may be provided on the solder joined surface of the heat sink 50. An uneven oxide film may be provided on the solder joined surface of the conductive spacer 70.

The arrangement of the uneven oxide film is not particularly limited. The uneven oxide films may be arranged in a dispersed manner at a predetermined pitch. As shown in FIG. 12, the uneven oxide film may be provided at an area corresponding to the vicinity of the center of the element or areas corresponding to four corners on the heat sink 50 or the conductive spacer 70.

### Third Embodiment

The present embodiment is a modification of the preceding embodiment(s) as a basic configuration and may incorporate description of the preceding embodiment(s). In the preceding embodiment(s), the grain size of the solder is reduced by providing the wire pieces or the uneven oxide film. Alternatively, unevenness (projections and recesses) may be provided on an inner peripheral end of the groove for accommodating the overflowing solder.

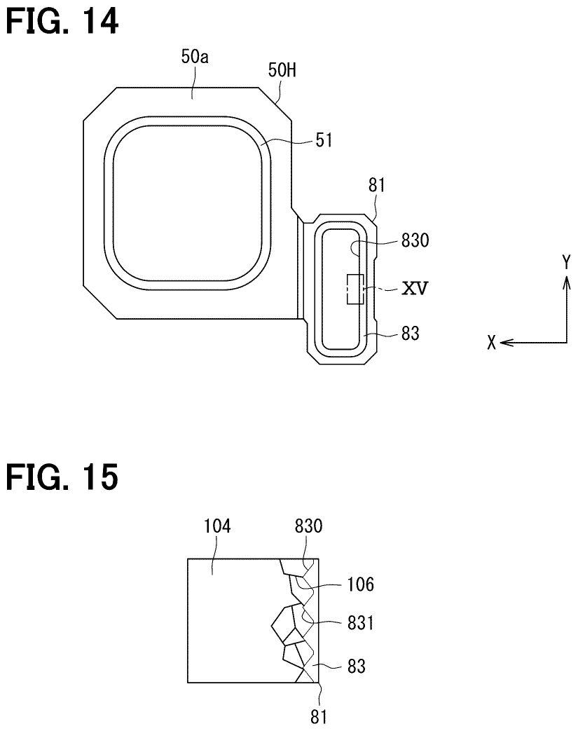

FIG. 14 is a plan view illustrating the heat sink 50H including the joint portion 81 in a semiconductor device 20 according to the present embodiment. FIG. 14 is a plan view seen from the facing surface 50a side. FIG. 15 is an enlarged view of a region XV indicated by a dashed line in FIG. 14. FIG. 15 shows the solder 104 disposed on the joint portion 81. In FIG. 15, only a part of the grain boundaries 106 is shown.

Similar to the preceding embodiment(s), the joint portion 81 is provided integrally and continuously with the heat sink 50H. As shown in FIG. 14, the heat sink 50H has a groove 51. The joint portion 81 also has a groove 83. As shown in FIG. 15, in the plan view, an inner peripheral end 830 of the groove 83 has a continuously uneven shape. The joint portion 81 has an uneven portion 831 on the inner peripheral end 830 of the groove 83. As an example, the uneven portion 831 is provided over the entire length of the groove 83.

The solder 104 grows into grains during solidification, starting from recesses and/or protrusions of the uneven portion 831 provided on the inner peripheral end 830 of the groove 83. Since the crystal grains grow from the unevenness as described above, the crystal grains in the solder 104 become smaller. The other configurations of the present embodiment are similar to those of the preceding embodiment(s).

### Summary of Third Embodiment

According to the configurations of the present embodiment described above, the similar effects to those of the preceding embodiment(s) can be achieved. Specifically, the inner peripheral end 830 of the groove 83, which accommodates the overflowing solder 104, has the continuous uneven shape. When the solder 104 solidifies, the grains grow from the unevenness of the inner peripheral end 830 as the starting point. The uneven portion 831 serves as the starting point of solidification. By having the unevenness on the inner peripheral end 830 of the groove 83, the grain size of the solder 104 can be made smaller than the grain size of the solders 103H and 103L, and thus the EM lifetime can be improved.

Although an example in which the uneven portion 831 is provided over the entire length of the groove 83 has been illustrated, the present disclosure is not limited to this example. The uneven portion 831 may be provided at least at a portion of the entire length of the groove 83. By making the inner peripheral end 830 of the groove 83 uneven at least at a part, the grain size of the solder 104 can be made smaller than the grain size of the solders 103H and 103L.

In addition, when the heat sink 50H including the joint 81 and the heat sink 50L including the joint portion 82 are the common members, the joint portion 82 also has the uneven portion 831 on the inner peripheral end 830 of the groove 83. In this case, the solder 105 can also be made smaller in size.

### Modification

Although an example in which the uneven portion 831 is provided in the groove 83 has been illustrated, the present disclosure is not limited to this example. The uneven portion may be provided on the inner peripheral end of the groove 51 of the heat sink 50. The uneven portion may be provided on an inner peripheral end of the groove 51 of the heat sink 50H. The uneven portion may be provided on an inner peripheral end of the groove 51 of the heat sink 50L. The uneven portion may be provided on each of the groove 51 and the groove 83.

### Fourth Embodiment

The present embodiment is a modification of the preceding embodiment(s) as a basic configuration and may incorporate description of the preceding embodiment(s). In the preceding embodiment(s), the grain size of the solder is reduced by devising the connection target to be connected by the solder. Alternatively, the grain size of the solder may be made smaller by devising the solder.

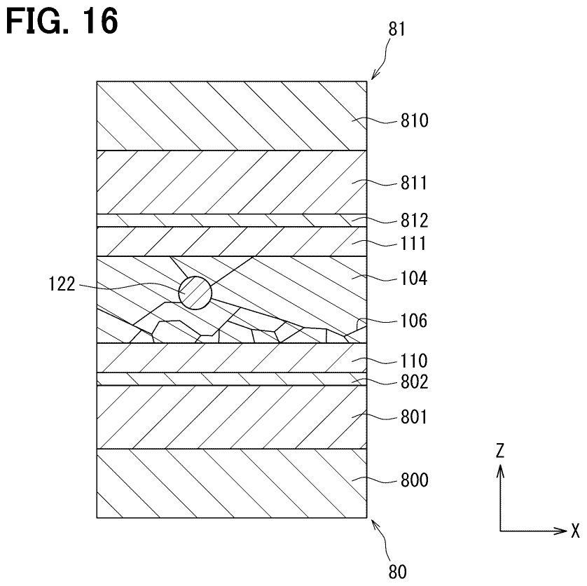

FIG. 16 is a cross-sectional view illustrating the joining structure of the joint portions 80 and 81 in the semiconductor device 20 according to the present embodiment. FIG. 16 corresponds to FIG. 8.

As shown in FIG. 16, the solder 104 has conductive balls 122 added thereto. The ball 122 is mainly composed of Ni or Cu. Such balls 122 will be also referred to as Ni balls or Cu balls. By appropriately setting the diameter of the balls 122, it is possible to ensure, for example, a minimum thickness of the solder 104.

Due to the presence of the balls 122, the solder 104 grows into grains starting from the balls 122 when solidifying. Since the grain growth starts from the balls 122 as the starting points, the crystal grains of the solder 104 are smaller than in a configuration in which the balls 122 are not added. The other configurations are similar to those of the preceding embodiment(s) described above.

### Summary of Fourth Embodiment

According to the configuration described in the present embodiment, it is possible to achieve the similar effects to those achieved by the configuration of the preceding embodiment(s) described above. Specifically, the balls 122 are added to the solder 104. When the solder 104 solidifies, grains grow from the balls 122 as the starting points. The ball 122 serves as the starting point of solidification. By providing the balls 122, the grain size of the solder 104 can be made smaller than the grain size of the solders 103H and 103L, and thus the EM lifetime can be improved.

The effects of the balls 122 were also confirmed through a prototype. It was confirmed that the grain size of the solder 104 was reduced by adding the balls 122. It was also confirmed that the disappearance of the alloy layers 110 and 111 was slowed down, that is, the progression of EM could be slowed down. In this case, the Ni layers 801 and 811 were formed by electroless NiP plating. The composition of the alloy layers 110 and 111 was (Ni—Cu)₃Sn₄.

### Modifications

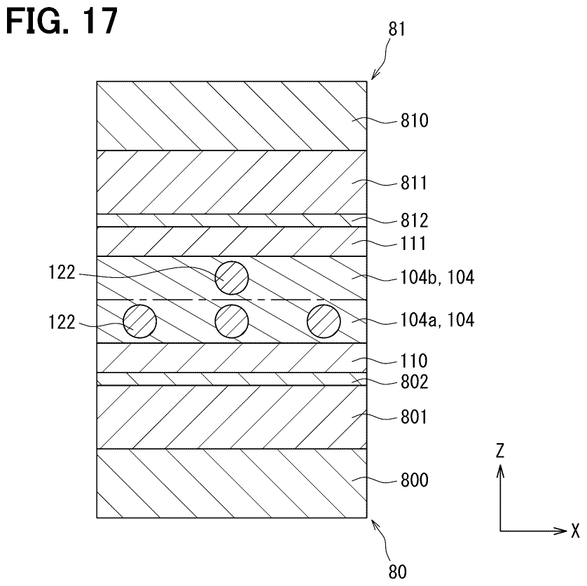

The solder 104 may have a multi-layer structure, and the occupancy rate of the balls 122 per unit volume may differ from layer to layer. In an example shown in FIG. 17, the solder 104 has a first layer 104a and a second layer 104b. The first layer 104a is a layer adjacent to the joint portion 80, and the second layer 104b is a layer adjacent to the joint portion 81. FIG. 17 corresponds to FIG. 16. For convenience, the illustration of the grain boundaries 106 are omitted in FIG. 17.

In the example shown in FIG. 17, the occupancy rate of the balls 122 in the first layer 104a is higher than the occupancy rate of the balls 122 in the second layer 104b. The amount of the balls 122 in the first layer 104a is larger than that in the second layer 104b. With this configuration, the grain size of the second layer 104b can be made small, while the grain size of the first layer 104a can be made further smaller. Therefore, in a configuration in which the EM is likely to progress due to the output current, the EM lifetime can be improved.

In addition, by making the diameters of the balls 122 different between the first layer 104a and the second layer 104b, the occupancy rate of the balls 122 in the first layer 104a may be made higher than the occupancy rate of the balls 122 in the second layer 104b. Both the amount and the diameter of the balls may be varied between the first layer 104a and the second layer 104b.

The occupancy rate of the balls 122 in the second layer 104b may be higher than the occupancy rate of the balls 122 in the first layer 104a. With this configuration, the grain size of the first layer 104a can be made small, while the grain size of the second layer 104b can be made further smaller. Therefore, in a configuration in which the EM is likely to progress due to the reverse current, the EM lifetime can be improved.

The two-layer structure of the solder 104 can be realized, for example, by arranging two layers of solder foil having different contents of the balls. Alternatively, three layers of solder foil without balls may be laminated, and the balls 122 may disposed between the solder foils, with the number and/or diameter of the balls 122 being different between the solder foils. The number of layers of the solder 104 is not limited to two. The number of layers of the solder 104 may be three or more.

Although an example in which the balls 122 are disposed in the solder 104 has been illustrated, the present disclosure is not limited to this example. The balls 122 can be disposed in at least one of the plurality of solders 100, excluding the solders 103H and 103L.

### OTHER EMBODIMENTS

The disclosure in the specification, the drawings and the like is not limited to the embodiments illustrated hereinabove. The disclosure encompasses the illustrated embodiments and modifications by those skilled in the art based thereon. For example, the disclosure is not limited to the parts and/or combinations of elements shown in the embodiments. The disclosure may be implemented in various combinations. The disclosure may have additional parts that may be added to the embodiment(s). The disclosure encompasses modifications in which components and/or elements are omitted from the embodiment(s). The disclosure encompasses the replacement or combination of components and/or elements between one embodiment and another. The technical scopes disclosed in the disclosure are not limited to the description of the embodiments. The several technical scopes disclosed are indicated by the description of the claims, and should be further understood to include meanings equivalent to the description of the claims and all modifications within the scope.

The disclosure in the specification, the drawings and the like is not limited by the description of the claims. The disclosure in the specification, the drawings, and the like encompasses the technical ideas described in the claims, and further extends to a wider variety of technical ideas than those in the claims. Therefore, various technical ideas can be extracted from the disclosure of the specification, the drawings, and the like without being restrained by the description of the claims.

When an element or layer is described to be “on”, “coupled”, “connected”, or “joined”, it may be directly on, coupled, connected, or joined to another element or another layer, and further an intervening element or an intervening layer may exist. In contrast, when an element is described to be “directly disposed on”, “directly coupled to,” “directly connected to”, or “directly combined with” another element or another layer, there are no intervening elements or layers present. Other terms used to describe the relationships between elements (for example, “between” vs. “directly between”, and “adjacent” vs. “directly adjacent”) should be interpreted similarly. As used herein, the term “and/or” includes any combination and all combinations relating to one or more of the related listed items. For example, the term A and/or B includes only A, only B, or both A and B.

Spatially relative terms “inner”, “outer”, “back”, “below”, “low”, “above”, “high”, and the like are used herein to facilitate description of a relationship of one element or a feature to another element or feature as illustrated. Spatial relative terms can be intended to include different orientations of a device in use or operation, in addition to the orientations illustrated in the drawings. For example, when a device in a drawing is turned over, elements described as “below” or “directly below” other elements or features are oriented “above” the other elements or features. Therefore, the term “below” can include both above and below. The device may be oriented in another direction (rotated 90 degrees or in any other direction) and the spatially relative terms used herein are interpreted accordingly.

The vehicle drive system 1 is not limited to the structure described above in the embodiment(s). An example in which the vehicle drive system 1 has one motor generator 3 has been illustrated. However, the present disclosure is not limited to the example illustrated. The vehicle drive system 1 may have multiple motor generators. An example in which the electric power conversion device 4 includes the inverter 6 as the electric power conversion device has been illustrated. However, the present disclosure is not limited to the example illustrated. For example, the electric power conversion device 4 may include multiple inverters. As another example, the electric power conversion device 4 may include at least one inverter and a converter. As further another example, the electric power conversion device 4 may include a converter only.

The switching element is not limited to the IGBT 11. For example, the switching element may be a metal oxide semiconductor field effect transistor (MOSFET). In a case of an n-channel MOSFET, the source electrode corresponds to the upper electrode, and the drain electrode corresponds to the lower electrode. In the case of a MOSFET, the freewheeling diode may be provided by a parasitic diode (body diode) or an external diode.

An example in which the semiconductor device 20 includes only one semiconductor element 40 constituting each arm has been illustrated. However, the present disclosure is not limited to this example. The semiconductor device 20 may include multiple semiconductor elements 40 each constituting one arm. That is, multiple semiconductor elements 40H may be connected in parallel to one another to form one arm 9H, and multiple semiconductor elements 40L may be connected in parallel to one another to form one arm 9L.

An example in which the rear surfaces 50b and 60b of the heat sinks 50 and 60 are exposed from the sealing body 30 has been illustrated. However, the present disclosure is not limited to this example. At least one of the rear surfaces 50b and 60b may be covered with the sealing body 30. At least one of the rear surfaces 50b and 60b may be covered with an insulating member (not shown) separate from the sealing body 30. The semiconductor device 20 may not include the sealing body 30.

An example in which the semiconductor device 20 includes the sealing body 30 has been illustrated. However, the present disclosure is not limited to this example. The sealing body 30 may be eliminated.

What is claimed is:

1. A semiconductor device comprising:
a plurality of semiconductor elements each having a signal pad and an upper electrode as a main electrode on an upper surface, and a lower electrode as a main electrode on a lower surface, which is opposite to the upper surface in a thickness direction, the lower electrode having an area larger than that of the upper electrode in a plan view when viewed in the thickness direction; and
a plurality of conductors electrically connected to the main electrodes through a plurality of solders, wherein
the plurality of semiconductor elements includes a first semiconductor element constituting an upper arm of an upper-lower arm circuit, and a second semiconductor element constituting a lower arm of the upper-lower arm circuit, the first semiconductor element and the second semiconductor element are arranged side by side in an arrangement direction perpendicular to the thickness direction so that the upper surface of the first semiconductor element and the upper surface of the second semiconductor element are on a same side in the thickness direction,
the plurality of solders includes a first upper solder, a first lower solder, a second upper solder, a second lower solder, and a relay solder,
the plurality of conductors includes a first upper conductor connected to the upper electrode of the first semiconductor element through the first upper solder, a first lower conductor connected to the lower electrode of the first semiconductor element through the first lower solder, a second upper conductor connected to the upper electrode of the second semiconductor element through the second upper solder, a second lower conductor connected to the lower electrode of the second semiconductor element through the second lower solder, and a joint conductor connecting the first upper conductor and the second lower conductor through the relay solder,
each of the plurality of solders contains copper (Cu) and tin (Sn),
each of solder connection targets to be connected through at least one of the plurality of solders has a nickel (Ni) layer,
a grain size of at least one of the first upper solder, the second upper solder, or the relay solder is smaller than a grain size of the first lower solder and the second lower solder,
the at least one of the first upper solder, the second upper solder, or the relay solder having the grain size smaller than the grain size of the first lower solder and the second lower solder is a small-grain solder, and
the small-grain solder or at least one of the solder connection targets connected through the small-grain solder has a starting point of solidification for reducing the grain size of the small-grain solder inside the small-grain solder or on a surface of the at least one of the solder connection targets.

2. The semiconductor device according to claim 1, wherein
the first upper conductor has a first body portion and a first spacer portion that is interposed between the upper electrode of the first semiconductor element and the first body portion,
the second upper conductor has a second body portion and a second spacer portion that is interposed between the upper electrode of the second semiconductor element and the second body portion,
the first upper solder is interposed between the upper electrode of the first semiconductor element and the first spacer portion, and between the first spacer portion and the first body portion, and
the second upper solder is interposed between the upper electrode of the second semiconductor element and the second spacer portion, and between the second spacer portion and the second body portion.

3. The semiconductor device according to claim 1, wherein
the joint conductor is a first joint conductor, and the relay solder is a first relay solder,
the plurality of conductors includes a main terminal and a second joint conductor that connects the second upper conductor and the main terminal through a second relay solder,
a grain size of the second relay solder is smaller than the grain size of the first lower solder and the second lower solder.

4. The semiconductor device according to claim 1, wherein
the starting point is provided by a plurality of wire pieces disposed inside the small-grain solder and fixed to the surface of the at least one of the solder connection targets.

5. The semiconductor device according to claim 1, wherein
at least one of the plurality of conductors connected through the small-grain solder as the at least one of the solder connection targets has an uneven oxide film on the Ni layer,
the uneven oxide film contains Ni as a main component and has continuous unevenness on a surface thereof, and
the starting point is provided by a void that is present over the uneven oxide film.

6. The semiconductor device according to claim 1, wherein
at least one of the plurality of conductors connected through the small-grain solder as the at least one of the solder connection targets is formed with a groove for accommodating an overflowing solder;
the groove has continuous unevenness on an inner peripheral end thereof, and
the starting point is provided by at least one of a projection or a recess provided by the continuous unevenness on the inner peripheral end of the groove.

7. The semiconductor device according to claim 1, wherein
the small-grain solder has a conductive ball added therein, and
the starting point is provided by the conductive ball.

8. The semiconductor device according to claim 7, wherein
the conductive ball contains Ni or Cu.
